(19) United States
(12) Patent Application Publication
(10) Pub. No.: US 2025/0364960 A1
(43) Pub. Date: Nov. 27, 2025

(54) SWITCHED INPUT ATTENUATOR FOR MULTIPLE AMPLIFIER CALIBRATIONS

(71) Applicant: SKYWORKS SOLUTIONS, INC., Irvine, CA (US)

(72) Inventors: Nathan Lucas Nuzum, Quasqueton, IA (US); Yulin Deng, Cedar Rapids, IA (US)

(21) Appl. No.: 19/214,475

(22) Filed: May 21, 2025

Related U.S. Application Data
(60) Provisional application No. 63/651,748, filed on May 24, 2024.

(51) Int. Cl. H03F 3/24

(52) U.S. Cl. CPC H03F 3/245; H03F 2200/451

(57) ABSTRACT

A radio frequency power amplifier system includes an input to receive an input signal; an output to provide an amplified signal; a switched input attenuator coupled to the input and including an attenuation path having an attenuation cell and a bypass path in parallel with the attenuation path, the bypass path configured to selectively bypass the attenuation cell; a radio frequency power amplifier coupled between the switched input attenuator and the output, the radio frequency power amplifier having a plurality of modes of operation including a first mode and a second mode different from the first mode; and a controller coupled to the switched input attenuator and configured to control an operational state of the switched input attenuator based on a mode of operation of the radio frequency power amplifier.

### CROSS-REFERENCE TO RELATED APPLICATIONS

This application claims priority under 35 U.S.C. § 119(e) to U.S. Provisional Patent Application 63/651,748 titled SWITCHED INPUT ATTENUATOR FOR MULTIPLE AMPLIFIER CALIBRATIONS, filed on May 24, 2024, the contents of which are incorporated herein by reference in their entirety for all purposes.

### BACKGROUND

This disclosure generally relates to switched input attenuators for improved characteristics of radio frequency (RF) power amplifier systems. An RF power amplifier system may have different modes of operation and require different calibrations for each mode. The different modes of operation may be responsive to different input signals received by the RF power amplifier system.

Attenuators generally reduce the power of a signal, such as an electromagnetic or an RF signal, without substantially distorting the waveform of the signal.

### SUMMARY OF THE INVENTION

Aspects and examples are directed to radio frequency power amplifier systems with switched input attenuators. A switched input attenuator may be coupled between an input of the radio frequency power amplifier system and an input of the radio frequency power amplifier in the system to selectively attenuate an input signal before amplification, depending on the mode of operation of the system.

The switched input attenuator may allow the radio frequency power amplifier system to satisfy certain performance requirements while operating under different modes and working with different input signals.

According to at least one aspect of the present disclosure, a radio frequency power amplifier system is described. In one embodiment, the radio frequency power amplifier system includes an input to receive an input signal; an output to provide an amplified signal; a switched input attenuator coupled to the input and including an attenuation path having an attenuation cell and a bypass path in parallel with the attenuation path, the bypass path being configured to selectively bypass the attenuation cell; a radio frequency power amplifier coupled between the switched input attenuator and the output, the radio frequency power amplifier having a plurality of modes of operation including a first mode and a second mode different from the first mode; and a controller coupled to the switched input attenuator and configured to control an operational state of the switched input attenuator based on a mode of operation of the radio frequency power amplifier.

In some embodiments, the first mode of the radio frequency power amplifier system is an envelope tracking mode and the second mode of the radio frequency power amplifier system is an average power tracking mode. In some embodiments, the first mode of the radio frequency power amplifier system is a broad-band mode, and the second mode of the radio frequency power amplifier system is a narrow-band mode. In some embodiments, the first mode of the radio frequency power amplifier system corresponds to a first operating frequency range and the second mode of the radio frequency power amplifier system corresponds to a second operating frequency range different from the first operating frequency range.

In at least one embodiment, the bypass path of the radio frequency power amplifier system includes a bypass switch coupled between an input of the switched input attenuator and an output of the switched input attenuator.

In some embodiments, the attenuation cell of the radio frequency power amplifier system includes a first switch, a resistive network, and a second switch coupled between the input of the switched input attenuator and the output of the switched input attenuator, the resistive network being coupled between the first switch and the second switch and configured to provide a first desired level of attenuation from the input to the radio frequency power amplifier.

In at least one embodiment, the bypass switch of the radio frequency power amplifier system has substantially similar parasitic characteristics as the first switch and the second switch combined.

In at least one embodiment, the resistive network of the radio frequency power amplifier system is one of a Pi-network, a T-network, and a bridged T-network.

In certain embodiments, the plurality of modes of operation of the radio frequency power amplifier system further includes a third mode different from the first mode and the second mode, the switched input attenuator further comprising: a second attenuation path having a second attenuation cell configured to provide a second desired level of attenuation from the input to the radio frequency power amplifier; and a second bypass path in parallel with the second attenuation path and configured to bypass the second attenuation cell.

In at least one embodiment, the attenuation cell of the radio frequency power amplifier system is electrically arranged in parallel with the second attenuation cell. In at least another embodiment, the attenuation cell of the radio frequency power amplifier system is electrically arranged in series with the second attenuation cell.

In some embodiments, the switched input attenuator of the radio frequency power amplifier system further includes a shunt switch coupled between the resistive network and a reference node and configured to selectively connect the resistive network to the reference node.

In at least one embodiment, the shunt switch of the radio frequency power amplifier system includes a plurality of switching elements selected to reduce the possibility of a breakdown voltage being reached in any of the plurality of switching elements.

In some embodiments, the radio frequency power amplifier system further includes a balun coupled between the radio frequency power amplifier and the output.

In at least one embodiment, the switched input attenuator of the radio frequency power amplifier system is formed on a silicon-on-insulator integrated circuit die.

According to at least another aspect of the present disclosure, a method of operating a radio frequency power amplifier system is described. In one embodiment, the method includes receiving a first input signal; attenuating the first input signal via an attenuation path to provide an attenuated signal; amplifying the first attenuated signal using a radio frequency power amplifier having a plurality of modes of operation, the radio frequency power amplifier operating in a first mode of the plurality of modes; receiving a second input signal; bypassing the attenuation path to provide a substantially unattenuated signal; and amplifying the substantially unattenuated signal using the radio frequency power amplifier operating in a second mode different from the first mode.

In some embodiments, the first mode described in the method is an envelope tracking mode and the second mode described in the method is an average power tracking mode, or vice versa. In some embodiments, the first mode described in the method is a broad-band mode and the second mode described in the method is a narrow-band mode, or vice versa. In some embodiments, the first mode described in the method corresponds to a first operating frequency range and the second mode described in the method corresponds to a second operating frequency range different from the first operating frequency range.

In at least one embodiment, bypassing the attenuation path described in the method includes switching a bypass switch in a bypass path in parallel with the attenuation path, and the attenuation path described in the method includes a switch and a resistive network coupled to the switch.

Among other advantages, the radio frequency power amplifier system and the method described herein may allow multiple calibrations and straightforward operation of the same system with respect to different modes of operation of the system to satisfy certain performance requirements under each mode. The switched input attenuator in the radio frequency power amplifier system may be simple to operate and integrate into the system and may provide consistent performances.

Still, other aspects, examples, and advantages of these exemplary aspects and examples are discussed in detail below. Examples disclosed herein may be combined with other examples in any manner consistent with at least one of the principles disclosed herein, and references to “an example/embodiment,” “some examples/embodiments,” “an alternate example/embodiment,” “various examples/embodiments,” “one example/embodiment” or the like are not necessarily mutually exclusive and are intended to indicate that a particular feature, structure, or characteristic described may be included in at least one example. The appearances of such terms herein are not necessarily all referring to the same example.

### BRIEF DESCRIPTION OF THE DRAWINGS

Various aspects of at least one example are discussed below with reference to the accompanying figures, which are not intended to be drawn to scale. The figures are included to provide illustration and a further understanding of the various aspects and examples, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 illustrates a schematic circuit diagram of an example radio frequency power amplifier system including a switched input attenuator;

FIG. 2 illustrates a schematic circuit diagram showing an example implementation of the example radio frequency power amplifier system illustrated in FIG. 1;

FIG. 3 illustrates a schematic circuit diagram of another example radio frequency power amplifier system including a switched input attenuator having multiple attenuation cells; and

FIGS. 4A and 4B illustrate measured and calculated results of implementing a switched input attenuator to satisfy a maximum gain requirement under different average power tracking modes of an example radio frequency power amplifier system.

### DETAILED DESCRIPTION

Aspects of the present disclosure are directed to radio frequency (RF) power amplifier systems having switched input attenuators that provide multi-mode operation and/or calibration as well as simplified control to work with input signals of various characteristics. RF power amplifier systems operating under different modes may require different input signal attenuation before amplification to satisfy certain system performance requirements relating to power gain, power efficiency, amplification linearity, etc. The switched input attenuators disclosed herein may be capable of selectively providing attenuated or substantially unattenuated input signals to be amplified under different modes of operation of the RF power amplifier systems. In some examples, individual attenuation cells of the switched input attenuators are either selected or bypassed in response to the current mode of operation of the RF power amplifier systems.

The switched input attenuators disclosed herein may also be capable of providing multiple levels of attenuation through multiple attenuation cells. Different attenuation levels may be selected by, for example, selectively connecting in parallel, series, or cascade one or more attenuation cells of various attenuation capabilities. Thereby, the total attenuation of the switched input attenuator may be altered, resulting in different levels of attenuation. Additionally, the switched attenuator may include one or more attenuation networks (e.g., networks of resistive elements) that compensate for deviations introduced by, for example, manufacturing variation in the fabrication of resistive elements.

It is to be appreciated that examples of the systems and methods discussed herein are not limited in application to the details of construction and the arrangement of components set forth in the following description or illustrated in the accompanying drawings. The systems and methods are capable of implementation in other examples and of being practiced or carried out in various ways. Examples of specific implementations are provided herein for illustrative purposes only and are not intended to be limiting.

Also, the phraseology and terminology used herein are for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. Any references to front and back, left and right, top and bottom, upper and lower, and vertical and horizontal are intended for convenience of description, not to limit the present systems and methods or their components to any one positional or spatial orientation.

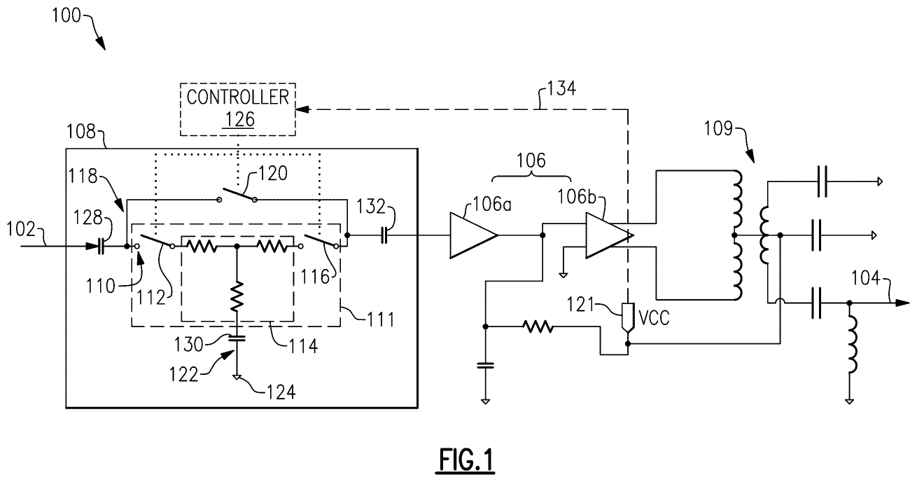

FIG. 1 illustrates an example RF power amplifier system 100 having a switched input attenuator 108. In one embodiment, the RF power amplifier system 100 receives an input signal at input 102 and provides an amplified output signal at output 104. The switched input attenuator 108 may be coupled between the input 102 and one or more RF power amplifiers 106 (e.g., RF power amplifiers 106a and 106b) to selectively attenuate the input signal before the input signal is amplified.

Referring to FIG. 1, in one embodiment, the switched input attenuator may include an attenuation path 110 and a bypass path 118 in parallel with the attenuation path 110. The attenuation path 110 may include an attenuation cell 111, which includes attenuation switches 112 and 116 and a resistive network 114. The resistive network 114 may be coupled between the attenuation switches 112 and 116. Bypass path 118 may include a bypass switch 120 coupled between an input and an output of the switched input attenuator 108 and configured to selectively bypass the attenuation cell 111. One or more capacitive elements 128 and 132 may be respectively coupled to the input and/or output of the switched input attenuator 108 to prevent direct-current transmission from the input of the switched input attenuator 108 to its output. The resistive network 114 may be coupled to a reference node 124 via a shunt terminal 122. The shunt terminal 122 may include one or more capacitive elements 130 and/or one or more shunt switches (not illustrated).

In various embodiments, the resistive network may be a Pi-network, a T-network, a delta network, or a bridged T-network. The resistive network may have a characteristic impedance of 50 Ohms. The resistive network may include multiple resistive elements. Each of the multiple resistive elements may be identical.

In one embodiment, the RF power amplifier system 100 may also include a balun 109 coupled between the one or more RF power amplifiers 106 and the output 104 for transforming a balanced amplified signal into an unbalanced amplified signal, or vice versa.

The attenuation switches 112, 116 and the bypass switch 120 may be optionally controlled by a controller 126 to switch between multiple operational states of the switched input attenuator 108 to either attenuate the input signal (i.e., attenuation state) or substantially not attenuate the input signal (i.e., bypass state) when the mode of operation of the RF power amplifier system 100 changes. In one embodiment, the controller 126 may control the operational state of the switched input attenuator 108 based on a signal 134 received from the power supply (VCC) 121 of at least one (e.g., the RF power amplifier 106b) of the one or more RF power amplifiers 106, which indicates the current mode of operation of the RF power amplifier system 100. In other embodiments, the controller 126 may control the operational state of the switched input attenuator 108 using other mechanisms that inform the mode of operation of the RF power amplifier system 100 without the signal 134. In some embodiments, the RF power amplifier system 100 may not include the controller 126 and the switches 112, 116, and 120 may be switched by other mechanisms (e.g., manually by a user, using control logic, etc.).

In one embodiment, when the signal 134 indicates that the RF power amplifier system 100 is operating under a broad-band envelope tracking (ET) mode (e.g., for New Radio), the controller 126 may open (disconnect) the switch 120 and close (connect) the switches 112 and 116 so that the input signal is routed through the attenuation path 110 and attenuated by the attenuation cell 111 before being amplified. Because the linearity and/or power efficiency requirement may be more difficult to satisfy for broad-band signals under ET modes, the attenuated input signal may allow reduced gain compression within at least one (e.g., the RF power amplifier 106b) of the one or more RF power amplifiers 106 and therefore improve the linearity and/or power efficiency of the amplified signal. On another occasion, when the signal 134 indicates that the RF power amplifier system 100 is operating under a narrow-band ET mode (e.g., for Long Term Evolution or LTE) where satisfactory linearity and/or power efficiency is easier to achieve, controller 126 may close the bypass switch 120 and open the attenuation switches 112 and 116 so that the input signal is routed through the bypass path 118 and remains substantially unattenuated before being amplified.

It should be understood that the bypass path 118 may still slightly attenuate the input signal in a non-substantial way for various reasons, such as due to minimal but non-zero resistance and other parasitic losses of the bypass switch 120 when closed and the transmission lines of the bypass path 118. In some embodiments, the bypass path 118 (or the entire switched input attenuator 108) may be preferably formed on a silicon-on-insulator integrated circuit die instead of a bulk silicon die to minimize the parasitic losses of the bypass path 118. In various embodiments, the parasitic losses of the bypass switch 120 may be chosen to balance out those of the attenuation switches 112 and 116 in the attenuation path 110. For example, the bypass switch 120 may include multiple switches.

In another embodiment, when the signal 134 indicates that the RF power amplifier system 100 is operating under a low-power (LP) average power tracking (APT) mode, the controller 126 may open the bypass switch 120 and close the attenuation switches 112 and 116 so that the input signal is routed through the attenuation path 110 and attenuated by the attenuation cell 111 before being amplified. The attenuated input signal may allow reduced gain of the one or more RF power amplifiers 106 while maintaining satisfactory linearity under the LP APT mode, which may be difficult to achieve with an unattenuated input signal under the same mode of the RF power amplifier system 100. On the other hand, when the signal 134 indicates that the RF power amplifier system 100 is operating under a high-power (HP) APT mode, the controller 126 may close the bypass switch 120 and open the attenuation switches 112 and 116 so that the input signal is routed through the bypass path 118 and remains substantially unattenuated before being amplified.

In another embodiment, the controller 126 may control the switched input attenuator 108 to attenuate the input signal when the input signal has a frequency range (e.g., high-band) that requires a mode of operation of the RF power amplifier system 100 with a certain set of performance characteristics. On another occasion, the controller 126 may control the switched input attenuator 108 to substantially not attenuate the input signal when the input signal has a different frequency range (e.g., mid-band or low-band) that requires a different mode of operation of the RF power amplifier system 100 with a different set of performance characteristics. It is to be appreciated that changing other characteristics of the input signal not mentioned above may also require the RF amplifier system 100 to change its mode of operation and cause corresponding switching of the switched input attenuator 108 (optionally by the controller 126) to satisfy certain performance requirement(s). The change in mode of operation may also include changes between an ET mode and an APT mode, or between other modes applicable to at least one of the one or more RF power amplifiers 106.

As illustrated by FIG. 1 and described above, in some embodiments, with the switched input attenuator 108 being switched between different operational states depending on the current mode of operation under which the RF power amplifier system 100 is operated, certain system performance requirement(s) relating to power gain, power efficiency, amplification linearity, etc., may be continuously satisfied across different modes of operation.

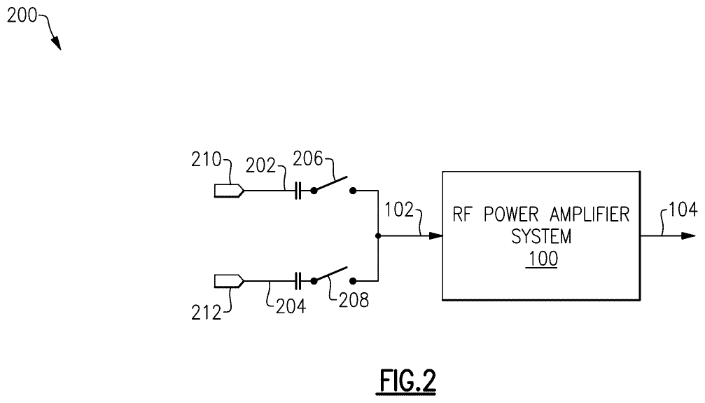

FIG. 2 shows a schematic circuit diagram 200 illustrating an example implementation of the radio frequency power amplifier system 100 coupled to multiple input signal paths. In various embodiments, different types or characteristics of different input signals may determine different modes of operation of the RF power amplifier system 100 and different corresponding operational states of the switched input attenuator 108. Therefore, in some of these embodiments, different input signals having different characteristics may be selectively transmitted to the RF power amplifier system 100 through separate signal input paths.

Referring to FIG. 2, in one embodiment, the input 102 of the RF power amplifier system 100 may be coupled to multiple switched input signal paths 202 and 204 through which different input signals are received. When an input switch 206 is closed (connected) and an input switch 208 is open (disconnected), an input signal 210 having a first characteristic (e.g., a broad-band New Radio signal) is received by the RF power amplifier system 100 via the input signal path 202. Input signal 212 is blocked and therefore not received by the RF power amplifier system 100. The RF power amplifier system 100 may recognize the first characteristic of the input signal 210 and responsively operate under a broad-band ET mode to reduce gain compression and improve linearity and/or power efficiency. In response to the broad-band ET mode, the RF power amplifier system 100 may control the switched input attenuator 108 (optionally by the controller 126) to operate in a state that routes the input signal 210 through the attenuation path 110. The one or more RF power amplifiers 106 in the RF power amplifier system 100 then amplify the attenuated input signal and output the amplified signal at the output 104.

On another occasion, when the input switch 208 is closed and the input switch 206 is open, the input signal 212 having a second characteristic (e.g., a narrow-band LTE signal) is received by the RF power amplifier system 100 via the input signal path 204. Input signal 210 is blocked and therefore not received by the RF power amplifier system 100. The RF power amplifier system 100 may recognize the second characteristic of the input signal 212 and responsively operate under a narrow-band ET mode. In response to the narrow-band ET mode, the RF power amplifier system 100 may control the switched input attenuator 108 (optionally by the controller 126) to operate in another state that routes the input signal 212 through the bypass path 118 so that the input signal 212 remains substantially unattenuated. The one or more RF power amplifiers 106 in the RF power amplifier system 100 then amplify the substantially unattenuated input signal and output the amplified signal at the output 104.

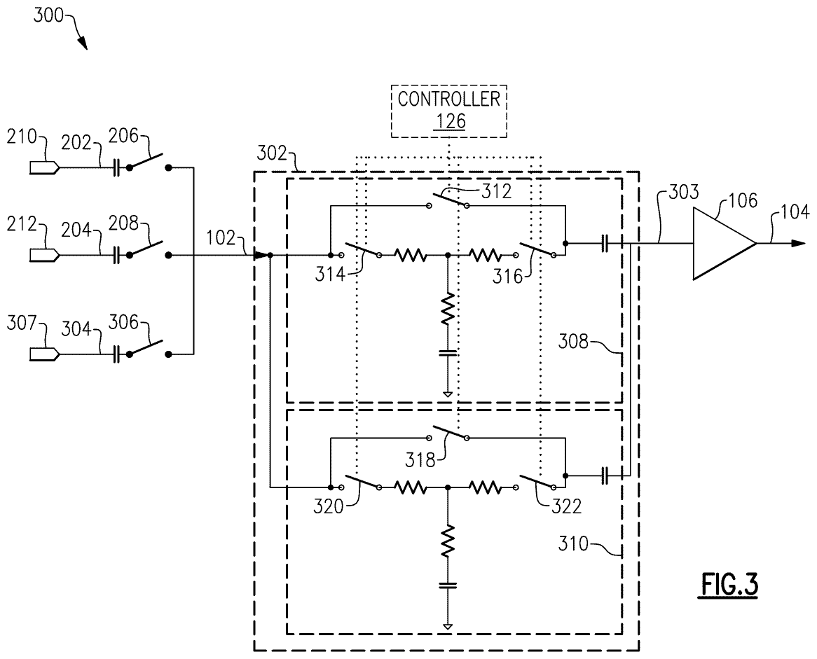

It is to be appreciated that one or more switched input signal paths (e.g., see FIG. 3) in addition to the input signal paths 202 and 204 may be implemented to couple to the input 102 of the RF power amplifier system 100, which may allow more complex routing options of multiple input signals and/or their combinations to be selectively received by the RF power amplifier system 100. In some embodiments, some or all of the multiple input signal paths, including the input signal paths 202, 204 and any additional input signal paths, may be constructed as part of the RF power amplifier system 100.

FIG. 3 illustrates another example RF power amplifier system 300 having a switched input attenuator 302 with multiple attenuation cells 308 and 310 and coupled between the input 102 and an input 303 of the RF power amplifier 106. In this embodiment, each attenuation cell 308, 310 may include a respective attenuation path and a respective bypass path in parallel with the respective attenuation path. Each attenuation path may or may not be constructed similarly to the attenuation path 110 in FIG. 1. Each bypass path also may or may not be constructed similarly to the bypass path 118 in FIG. 1 to bypass the respective attenuation path selectively. The attenuation cells 308 and 310 may be electrically arranged in parallel as shown in FIG. 3 but may also be arranged in series (not illustrated). All the switches in the switched input attenuator 302 may optionally be controlled by the controller 126 to configure the operational state of the switched input attenuator 302. As will be described in detail below, the switched input attenuator 302 may selectively provide multiple levels of attenuation of the input signals depending on the mode of operation of the RF amplifier system 300 and/or the performance requirement(s).

In this embodiment of FIG. 3, multiple signal input paths 202, 204, 304 may be coupled to the input 102 through which the RF power amplifier system 300 may selectively receive different input signals with various characteristics. Each signal input path 202, 204, 304 has a respective input switch 206, 208, 306 configured to only select one input signal to be received while the others are blocked and not received by the RF power amplifier system 300.

In one example, when the input switch 206 is closed and the input switches 208 and 306 are open, the input signal 210 having a first characteristic (e.g., low-to-mid-band or LMB) is received by the RF power amplifier system 300 while the input signals 212 and 307 are blocked. The first characteristic of the input signal 210 may drive the RF power amplifier system 300 into a first mode of operation (e.g., LMB mode). In response to the first mode, the operational state of the switched input attenuator 302 may be controlled (optionally by the controller 126) to close the bypass switches 312 and 318 and open the attenuation switches 314, 316, 320, 322 in the attenuation paths so that the input signal 210 is substantially unattenuated before being amplified.

On another occasion, when the input switch 208 is closed and the input switches 206 and 306 are open, the input signal 212 having a second characteristic (e.g., high-band or HB) is received by the RF power amplifier system 300 while the input signals 210 and 307 are blocked. The second characteristic of the input signal 212 may drive the RF power amplifier system 300 into a second mode of operation (e.g., HB mode) to satisfy certain performance requirement(s). In response to the second mode, the operational state of the switched input attenuator 302 may be controlled (optionally by the controller 126) to close the attenuation switches 314, 316, and the bypass switch 318 while opening the bypass switch 312 and the attenuation switches 320, 322 so that the input signal 212 is attenuated at a first level by the attenuation path of the attenuation cell 308 before being amplified.

In another example, in response to the second mode, the operational state of the switched input attenuator 302 may be controlled (optionally by the controller 126) to close the attenuation switches 320, 322 and the bypass switch 312 while opening the bypass switch 318 and the attenuation switches 314, 316 so that the input signal 212 is attenuated by the attenuation path of the attenuation cell 310 before being amplified. In some embodiments, the attenuation path of the attenuation cell 310 may include a resistive network constructed differently (e.g., different resistance and/or arrangement of individual resistors) from that in the attenuation path of the attenuation cell 308. This allows the option of attenuating the input signal 212 at a second level different from the first level before the input signal 212 is amplified. This example shows that the switched input attenuator 302 may allow the RF power amplifier system 300 to switch between different modes of operation either for the same input signal to satisfy different performance requirements or for different input signals.

On yet another occasion, when the input switch 306 is closed and the input switches 206 and 208 are open, the input signal 307 having a third characteristic (e.g., mid-band or MB) is received by the RF power amplifier system 300 while the input signals 210 and 212 are blocked. The third characteristic of the input signal 307 may drive the RF power amplifier system 300 into a third mode of operation (e.g., MB mode) to satisfy certain performance requirement(s). In response to the third mode, the operational state of the switched input attenuator 302 may be controlled (optionally by the controller 126) to close the attenuation switches 314, 316, 320, 322 while opening the bypass switches 312, 318 so that the input signal 307 is attenuated at a third level by both attenuation paths of the attenuation cells 308 and 310 before being amplified.

In other embodiments, the switched input attenuator 302 may further include one or more attenuation cells in addition to the attenuation cells 308 and 310. Each additional attenuation cell may or may not be constructed similarly to the attenuation cells shown in FIGS. 1 and 3. The attenuation cells in a switched input attenuator may be arranged in series, parallel, or cascade in various ways depending on the input signal characteristics, the amplifier characteristics, and the performance requirements. Switched input attenuators with even more attenuation cells may allow additional levels of attenuation of the input signals. In some of these embodiments, the RF power amplifier system 300 may further include (or be coupled to) one or more switched input signal paths in addition to the input signal paths 202, 204, 304. These additional switched input signal paths may allow more complex routing options of multiple input signals and/or their combinations to be selectively received by the RF power amplifier system 300.

The bypass switches, the attenuation switches, the shunt switches, and the input switches in the present disclosure may be constructed in a variety of manners depending upon the particular implementation. Any of the bypass switches, the attenuation switches, the shunt switches, and the input switches may be implemented as a single transistor or other component capable of being selectively placed in a conducting (closed or connected) state or a non-conducting (open or disconnected) state. A transistor, such as a Field Effect Transistor (FET), a Bipolar Junction Transistor (BJT), or others, may be a suitable component. Additionally, in embodiments, other elements may be used, such as Microelectromechanical System (MEMS) Switches, diodes, diode-connected transistors, PIN diodes, etc. In various embodiments, multiple components or switching elements may be connected together to form any of the bypass switches, the attenuation switches, the shunt switches, and the input switches.

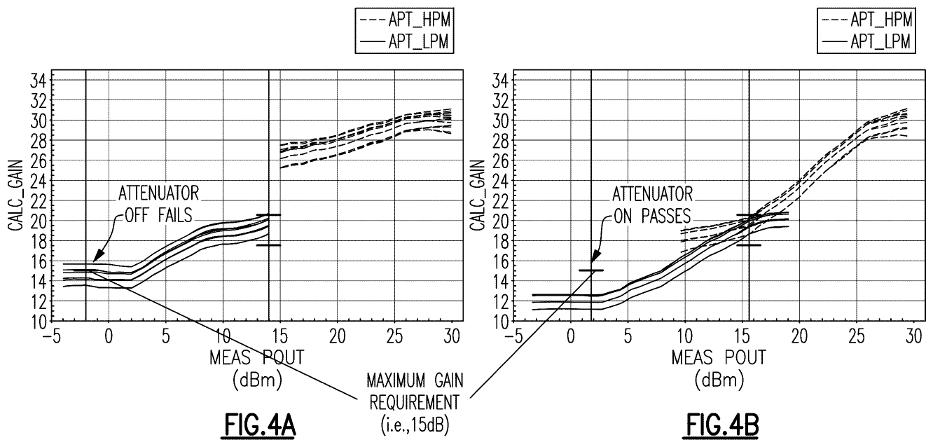

FIGS. 4A and 4B illustrate measured and calculated results of implementing a switched input attenuator described above to satisfy a maximum gain requirement under different APT modes of an example radio frequency power amplifier system. For measured amplifier power output (“MEAS POUT”) below 14 dBm, the RF power amplifier system operates in an APT low-power mode (“APT_LPM”). Referring to FIG. 4A, in one embodiment, when the switched input attenuator is switched off (i.e., the input signal is routed through the bypass path and substantially unattenuated), the topmost curve in the APT_LPM mode has a calculated power gain (“CALC_GAIN”) above the maximum gain requirement of 15 dB at a power output of −2 dBm. This shows that, when the switched input attenuator is operating in the bypass state, the RF power amplifier system fails the maximum gain requirement under the APT_LPM mode even if it may satisfy other performance requirements such as linearity.

Referring to FIG. 4B, on another occasion when the switched input attenuator is switched on (i.e., the input signal is routed through the attenuation path and attenuated accordingly by a resistive network in the attenuation path), all curves in the APT_LPM mode have a calculated power gain (“CALC_GAIN”) under 15 dB at a power output of −2 dBm. This shows that, when the switched input attenuator is operating at the attenuating state, the RF power amplifier system passes (i.e., satisfies) the maximum gain requirement under the APT_LPM mode while potentially also satisfying other performance requirements such as linearity.

Having described above several aspects of at least one example, it is to be appreciated that various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from the proper construction of the appended claims, and their equivalents.

What is claimed is:

1. A radio frequency power amplifier system comprising:
an input to receive an input signal;
an output to provide an amplified signal;
a switched input attenuator coupled to the input and including an attenuation path having an attenuation cell and a bypass path in parallel with the attenuation path, the bypass path configured to selectively bypass the attenuation cell;
a radio frequency power amplifier coupled between the switched input attenuator and the output, the radio frequency power amplifier having a plurality of modes of operation including a first mode and a second mode different from the first mode; and
a controller coupled to the switched input attenuator and configured to control an operational state of the switched input attenuator based on a mode of operation of the radio frequency power amplifier.

2. The radio frequency power amplifier system of claim 1, wherein the first mode is an envelope tracking mode and the second mode is an average power tracking mode.

3. The radio frequency power amplifier system of claim 1, wherein the first mode is a broad-band mode and the second mode is a narrow-band mode.

4. The radio frequency power amplifier system of claim 1, wherein the first mode corresponds to a first operating frequency range and the second mode corresponds to a second operating frequency range different from the first operating frequency range.

5. The radio frequency power amplifier system of claim 1, wherein the bypass path includes a bypass switch coupled between an input of the switched input attenuator and an output of the switched input attenuator.

6. The radio frequency power amplifier system of claim 5, wherein the attenuation cell includes a first switch, a resistive network, and a second switch coupled between the input of the switched input attenuator and the output of the switched input attenuator, the resistive network being coupled between the first switch and the second switch and configured to provide a first desired level of attenuation from the input to the radio frequency power amplifier.

7. The radio frequency power amplifier system of claim 6, wherein the bypass switch has substantially similar parasitic characteristics as the first switch and the second switch combined.

8. The radio frequency power amplifier system of claim 6, wherein the resistive network is one of a Pi-network, a T-network, and a bridged T-network.

9. The radio frequency power amplifier system of claim 6, wherein the plurality of modes of operation further includes a third mode different from the first mode and the second mode, the switched input attenuator further comprising:
a second attenuation path having a second attenuation cell configured to provide a second desired level of attenuation from the input to the radio frequency power amplifier; and
a second bypass path in parallel with the second attenuation path and configured to bypass the second attenuation cell.

10. The radio frequency power amplifier system of claim 9, wherein the attenuation cell is electrically arranged in parallel with the second attenuation cell.

11. The radio frequency power amplifier system of claim 9, wherein the attenuation cell is electrically arranged in series with the second attenuation cell.

12. The radio frequency power amplifier system of claim 1, wherein the switched input attenuator further includes a shunt switch coupled between the resistive network and a reference node and configured to selectively connect the resistive network to the reference node.

13. The radio frequency power amplifier system of claim 1, wherein the shunt switch includes a plurality of switching elements selected to reduce the possibility of a breakdown voltage being reached in any of the plurality of switching elements.

14. The radio frequency power amplifier system of claim 1, further comprising a balun coupled between the radio frequency power amplifier and the output.

15. The radio frequency power amplifier system of claim 1, wherein the switched input attenuator is formed on a silicon-on-insulator integrated circuit die.

16. A method of operating a radio frequency power amplifier system, the method comprising:
receiving a first input signal;
attenuating the first input signal via an attenuation path to provide an attenuated signal;
amplifying the first attenuated signal using a radio frequency power amplifier having a plurality of modes of operation, the radio frequency power amplifier operating in a first mode of the plurality of modes;
receiving a second input signal;
bypassing the attenuation path to provide a substantially unattenuated signal; and
amplifying the substantially unattenuated signal using the radio frequency power amplifier operating in a second mode different from the first mode.

17. The method of claim 16, wherein the first mode is an envelope tracking mode and the second mode is an average power tracking mode, or vice versa.

18. The method of claim 16, wherein the first mode is a broad-band mode and the second mode is a narrow-band mode, or vice versa.

19. The method of claim 16, wherein the first mode corresponds to a first operating frequency range and the second mode corresponds to a second operating frequency range different from the first operating frequency range.

20. The method of claim 16, wherein bypassing the attenuation path includes switching a bypass switch in a bypass path in parallel with the attenuation path, and the attenuation path includes a switch and a resistive network coupled to the switch.
